(19) United States
(12) Patent Application Publication
(10) Pub. No.: US 2025/0160109 A1
(43) Pub. Date: May 15, 2025

(54) LIGHT-EMITTING ELEMENT, METHOD AND APPARATUS FOR PRODUCING LIGHT-EMITTING ELEMENT, AND DISPLAY DEVICE

(71) Applicant: SHARP DISPLAY TECHNOLOGY CORPORAION, Kameyama City, Mie (JP)

(72) Inventor: Kazuki MARUHASHI, Kameyama City, Mie (JP)

(21) Appl. No.: 18/728,483

(22) PCT Filed: Mar. 23, 2022
(86) PCT No.: PCT/JP2022/013494

§ 371 Date: Jul. 12, 2024

(51) Int. Cl. H10K 50/115; H10K 71/15; H10K 101/30

(52) U.S. Cl. CPC H10K 50/115; H10K 71/15; H10K 2101/30

(57) ABSTRACT

A light-emitting element is provided with the following: a first electrode and a second electrode; and a quantum dot layer disposed between the first electrode and the second electrode, and including first quantum dots. The quantum dot layer includes a space absent from the first quantum dots penetrating the quantum dot layer in a thickness direction of the quantum dot layer. The space contains second quantum dots having a smaller particle diameter than the first quantum dots.

### TECHNICAL FIELD

The disclosure relates to a light-emitting element and other things.

### BACKGROUND ART

Patent Literature 1 discloses a light-emitting element including a quantum dot layer, and a technique of filling the gap between quantum dots (where current concentrates) with an insulating film.

### CITATION LIST

### Patent Literature

Patent Literature 1: Japanese Unexamined Patent Application Publication No. 2007-095685

### SUMMARY

### Technical Field

In the above technique, carrier injection into the quantum dots is hindered by the insulating film, thereby possibly degrading light emission efficiency.

### Solution to Problem

A light-emitting element according to one aspect of the disclosure is provided with the following: a first electrode and a second electrode; and a quantum dot layer disposed between the first electrode and the second electrode, and including first quantum dots. The quantum dot layer includes a space absent from the first quantum dots penetrating the quantum dot layer in the thickness direction of the quantum dot layer. The space contains second quantum dots having a smaller particle diameter than the first quantum dots.

### Advantageous Effect of Invention

The aspect of the disclosure can enhance the light emission efficiency of a light-emitting element.

### BRIEF DESCRIPTION OF DRAWINGS

FIG. 1 is a cross-sectional view of an example of the configuration of a light-emitting element according to a first embodiment.

FIG. 2 is a cross-sectional view of a quantum dot layer.

FIG. 3 is a graph showing the particle diameter distribution of the quantum dot layer.

FIG. 4 illustrates the particle diameter distribution of the quantum dot layer.

FIG. 5 illustrates the particle diameter distribution of the quantum dot layer.

FIG. 6 is a cross-sectional view of the quantum dot layer.

FIG. 7 is a schematic diagram illustrating an example of the configuration of a first quantum dot, and an example of the configuration of a second quantum dot.

FIG. 8 is a schematic diagram illustrating an example of the configuration of the first quantum dot, and an example of the configuration of the second quantum dot.

FIG. 9 is a schematic diagram illustrating the energy level of each quantum dot.

FIG. 10 is a schematic diagram illustrating the energy level of each quantum dot.

FIG. 11 is a schematic diagram illustrating an example of the configuration of a third quantum dot.

FIG. 12 is a flowchart showing a method for manufacturing the light-emitting element according to the first embodiment.

FIG. 13 is a cross-sectional view of the light-emitting element according to the first embodiment in the process of being manufactured.

FIG. 14 is a block diagram illustrating an apparatus that manufactures the light-emitting element according to the first embodiment.

FIG. 15 is a cross-sectional view of an example of the configuration of the light-emitting element according to a second embodiment.

FIG. 16 is a schematic diagram illustrating energy levels in the configuration in FIG. 15.

FIG. 17 is a cross-sectional view of the light-emitting element according to the second embodiment in the process of being manufactured.

FIG. 18 is a cross-sectional view of another example of the configuration of the light-emitting element according to the second embodiment.

FIG. 19 is a schematic diagram illustrating energy levels in the configuration in FIG. 18.

FIG. 20 is a cross-sectional view of an example of the configuration of the light-emitting element according to a third embodiment.

FIG. 21 is a schematic diagram illustrating energy levels in the configuration in FIG. 20.

FIG. 22 is a cross-sectional view of another example of the configuration of the light-emitting element according to the third embodiment.

FIG. 23 is a schematic diagram illustrating energy levels in the configuration in FIG. 22.

FIG. 24 is a cross-sectional view of an example of the configuration of a display device according to a fourth embodiment.

### DESCRIPTION OF EMBODIMENTS

### First Embodiment

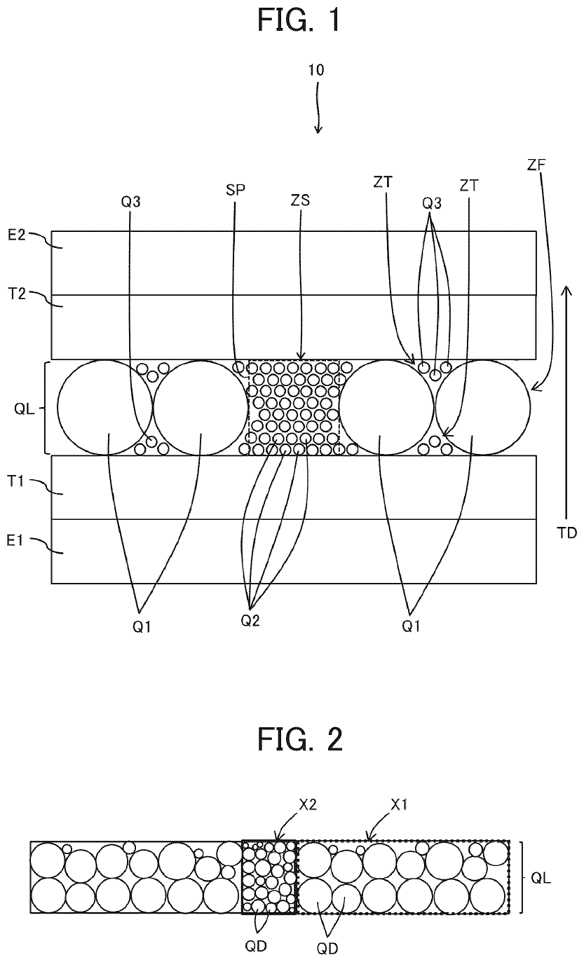

FIG. 1 is a cross-sectional view of an example of the configuration of a light-emitting element according to a first embodiment. The light-emitting element, 10, according to the first embodiment is provided with the following: a first electrode E1 and a second electrode E2; and a quantum dot layer QL disposed between the first electrode E1 and the second electrode E2, and including first quantum dots Q1. Quantum dots are dots whose maximum width (maximum diameter) measures 100 nm or less. The quantum dots may each have any shape within a range satisfying this maximum width; the shape is not limited to a spherical shape (circular shape in cross-sectional view). For instance, the quantum dots may each have an elliptic spherical shape (elliptic shape in cross-sectional view), a tridimensional shape having a polygonal cross-section, a bar-shaped tridimensional shape, a branch-shaped tridimensional shape, or a tridimensional shape having surface asperities; alternatively, each may have a shape with a combination of the these shapes.

The quantum dot layer QL is a layer including a plurality of quantum dots. The cross-sectional shape of the quantum dot layer does not necessarily have to be linear. The quantum dot layer QL does not have to have a uniform thickness; the layer may have different thicknesses as long as at least any region in cross-sectional view has a thickness equal to or larger than a certain thickness, and the layer's surface (at least one of the lower and upper surfaces) may have an asperity shape. The quantum dot layer QL can be also referred to as a quantum dot portion.

The first quantum dots Q1 can be semiconductor nanocrystal particles, and the first quantum dots Q1 may be electroluminescent substances that emit light having a wavelength corresponding to a band gap. The band gap varies depending on the particle diameter and composition of the first quantum dots Q1. The particle diameter of the first quantum dots Q1 measures 1.0 [nm] to 100 [nm] for instance, and may measure 3.0 [nm] to 20 [nm]. The first quantum dots Q1 may each have a spherical shape, an elliptic spherical shape, a polyhedral shape, a bar shape, a branched shape, or a tridimensional shape with surface asperities; alternatively, each may have a shape with a combination of these tridimensional shapes.

The quantum dot layer QL includes a space SP absent from the first quantum dots Q1 penetrating the quantum dot layer QL in a layer's thickness direction TD. The space SP contains second quantum dots Q2 having a smaller particle diameter than the first quantum dots Q1.

The second quantum dots Q2 can be also semiconductor nanocrystal particles. The second quantum dots Q2 may each have a spherical shape, an elliptic spherical shape, a polyhedral shape, a bar shape, a branched shape, or a tridimensional shape with surface asperities; alternatively, each may have a shape with a combination of these tridimensional shapes.

The band gap of the second quantum dots Q2 (e.g., the band gap of the Q2's cores) may be larger than the band gap of the first quantum dots Q1 (e.g., the band gap of Q1's cores). Carriers are less likely to enter the second quantum dots Q2 whose core's band gap is larger than the core's band gap of the first quantum dots Q1; even if having entered the second quantum dots Q2, carriers move to the first quantum dots Q1 quickly.

The band gap may be a gap between the energy level of the lowest unoccupied molecular orbital (LUMO) and the energy level of the highest occupied molecular orbital (HOMO), or a gap between the conduction band minimum (CBM) and the valence band maximum (VBM). Hereinafter, a “gap” shall mean the degree of a difference (the absolute value of a difference) and shall stand at zero or a positive value. The energy level of the lowest unoccupied molecular orbital (LUMO) and the energy level of the highest occupied molecular orbital (HOMO) are negative values (unit: eV) with vacuum level as a standard (zero). For instance, electron affinity is a gap between LUMO and vacuum level, and ionization energy is a gap between HOMO and vacuum level. In the following description, CBM may be substituted for LUMO, and VBM may be substituted for HOMO. Further, a smaller energy level (a smaller value of energy level) means that the energy level is more distant from vacuum level, that is, the level is deeper. Further, a larger energy level (a larger value of energy level) means that the energy level is closer to vacuum level, that is, the level is shallower. The cores of the second quantum dots Q2 have a bang gap of 5.8 eV or less, 4.0 eV or less, or 3.5 eV or less for instance.

The second electrode E2 is located higher than the first electrode E1. That is, the second electrode E2 is formed in a process step posterior to the process step of forming the first electrode E1. For instance, the second electrode E2 is disposed spatially farther from a pixel circuit substrate (which will be described later on) including thin-film transistors than the first electrode E1.

The light-emitting element 10 is provided with the following: a first carrier transport layer T1 disposed between the first electrode E1 and the quantum dot layer QL; and a second carrier transport layer T2 disposed between the quantum dot layer QL and the second electrode E2. For instance, where the first electrode E1 is an anode, and the second electrode E2 is a cathode, the first carrier transport layer T1 is a hole transport layer (HTL), and the second carrier transport layer T2 is an electron transport layer (ETL). Further, where the first electrode E1 is a cathode, and the second electrode E2 is an anode, the first carrier transport layer T1 is an electron transport layer (ETL), and the second carrier transport layer T2 is a hole transport layer (HTL).

The hole transport layer (HTL) is not limited to a single layer; the HTL may have a multilayer structure. Further, between the anode and hole transport layer (HTL) may be a hole injection layer (HIL). The hole injection layer (HIL) is not limited to a single layer; the HIL may have a multilayer structure. The electron transport layer (ETL) is not limited to a single layer; the ETL may have a multilayer structure. Further, between the cathode and electron transport layer (ETL) may be an electron injection layer (EIL). The electron injection layer (EIL) is not limited to a single layer; the EIL may have a multilayer structure.

In the quantum dot layer QL including quantum dots, it is conceivable that a hole from the anode and an electron from the cathode recombine together, thus generating an electron, which then goes back to a ground state, thus emitting light. Voltage application between the anode and cathode causes such recombination within the quantum dot layer QL.

The space SP may contain a second-quantum-dot assembly ZS including the second quantum dots Q2, so that a short circuit between the HTL and ETL can be prevented effectively. The second-quantum-dot assembly ZS may have a multilayer structure in which the second quantum dots Q2 are included in the individual layers. Further, the second-quantum-dot assembly ZS may be filled in the space SP. Either of these configurations can prevent a short circuit between the HTL and ETL effectively and can thus reduce an invalid current that does not contribute to the recombination.

Further, the volume of the space SP may be larger than the volume of each first quantum dot Q1. That is, in such a cross-sectional structure as illustrated in FIG. 1, the cross-sectional area of the space SP may be larger than the cross-sectional area of each first quantum dot Q1. In this case, an invalid current is reduced more effectively.

The quantum dot layer QL may include a first-quantum-dot assembly ZF including the first quantum dots Q1, and a third-quantum-dot assembly ZT including third quantum dots Q3 having a smaller particle diameter than the first quantum dots Q1. The third quantum dots Q3 may have a configuration identical to the configuration of the second quantum dots Q2 (i.e., the same material, the same size, the same structure, and the same band gap). The third quantum dots Q3 may have a larger band gap than the first quantum dots Q1.

The third-quantum-dot assembly ZT may be disposed in a space between the first carrier transport layer T1 and the first-quantum-dot assembly ZF being in contact with the first carrier transport layer T1. The third-quantum-dot assembly ZT may be disposed in a space between the second carrier transport layer T2 and the first-quantum-dot assembly ZF being in contact with the second carrier transport layer T2. The third-quantum-dot assembly ZT may be also disposed in each of these spaces.

The particle diameter of the second quantum dots Q2 can be eight-tenths or less, or six-tenths or less of the particle diameter of the first quantum dots Q1, or five-tenths or less, four-tenths or less, one-fourth or less, or two-tenths or less of the particle diameter of the first quantum dots Q1. That the particle diameter of the second quantum dots Q2 is smaller than the particle diameter of the first quantum dots Q1 can be defined in other words as that the average particle diameter of the second quantum dots within the second-quantum-dot assembly ZS is smaller than the average particle diameter of the first quantum dots within the first-quantum-dot assembly ZF. When at least one of each first quantum dot Q1 and each second quantum dot Q2 has a shape that is not a circular shape, a diameter with equal-area transformation into a spherical shape, for instance, can be a particle diameter.

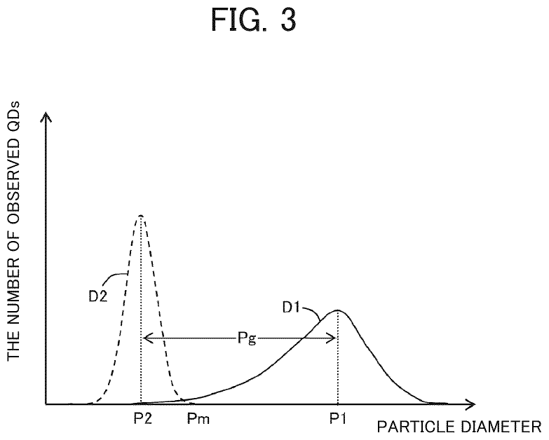

FIG. 2 is a cross-sectional view of the quantum dot layer. FIG. 3 illustrates the particle diameter distribution of the quantum dot layer. Reference is made to FIG. 2 and FIG. 3. The cross-section of the quantum dot layer QL parallel to its thickness direction and including the entire thickness direction was observed using a transmission electron microscope (hereinafter, referred to as a TEM) or other things, to conduct an examination between the particle diameter distribution, D1, of all quantum dots QD (e.g., 10 to 100 quantum dots) contained in a region X1 including the entire layer thickness direction, and the particle diameter distribution, D2, of all quantum dots QD (e.g., 10 to 100 quantum dots) contained in a region X2 including the entire layer thickness direction. The examination has revealed that the region X1 contains one or more quantum dots QD having a larger particle diameter than the maximum particle diameter, Pm, in the particle diameter distribution D2. Based on this fact, the quantum dots QD having a larger particle diameter than the maximum particle diameter Pm can be specified as the first quantum dots Q1; in addition, the space SP including the region X2 (a space absent from the first quantum dots Q1) can be specified; in addition, the quantum dots QD having a particle diameter equal to or smaller than the maximum particle diameter Pm in the particle diameter distribution D2 can be specified as the second quantum dots Q2 (those contained in the region X2) or the third quantum dots Q3 (those contained in the region X1).

Pm in FIG. 3 is the maximum of the particle diameters of all the quantum dots QD whose entire cross sections are observed in the region X2 (two sides of which in the layer thickness direction are equal to the thickness of the quantum dot layer QL); when all the quantum dots QD have a uniform particle diameter, this uniform particle diameter is to be defined as Pm. The particle diameter ratio of the first quantum dot Q1 to the maximum particle diameter Pm in the particle diameter distribution D2 may stand at, for example, 1.1 or greater, 1.2 or greater, 1.5 or greater, 2.0 or greater, 2.5 or greater, 3.0 or greater, 5.0 or greater, 8.0 or greater, or 10 or greater. The average particle diameter of a plurality of first quantum dots Q1 (QD having a larger particle diameter than Pm) in the region X1 may stand at 1.1 or greater of Pm, 1.2 or greater of Pm, 1.5 or greater of Pm, 2.0 or greater of Pm, 2.5 or greater of Pm, 3.0 or greater of Pm, 5.0 or greater of Pm, 8.0 or greater of Pm, or 10 or greater of Pm.

The figure shows the peak particle diameter, P1, (a particle diameter at which the number of dots peaks in D1) in the particle diameter distribution D1, and the peak particle diameter, P2, (a particle diameter at which the number of dots peaks in D2) in the particle diameter distribution D2; here, P1>P2 may be satisfied. The peak gap, Pg, (=P1−P2, P1>P2) may be equal to or larger than a standard deviation σ1 in the particle diameter distribution D1. The peak gap Pg (=P1−P2, P1>P2) may be 1.0 times or greater of (σ1+σ2), 1.2 times or greater of (σ1+σ2), or 1.5 times or greater of (σ1+σ2), where σ2 is a standard deviation in the particle diameter distribution D2. The area of the region X2 (the cross-sectional area of the space SP) may be smaller than the area of the region X1.

Further, the particle diameter P1 may be equal to the average particle diameter of the first quantum dots in the first-quantum-dot assembly ZF, and the particle diameter P2 may be equal to the average particle diameter of the second quantum dots in the second-quantum-dot assembly ZS. When a quantum dot observed using a TEM or other things has a non-circular cross section, its diameter with equal-area transformation into a circular shape may be defined as its particle diameter.

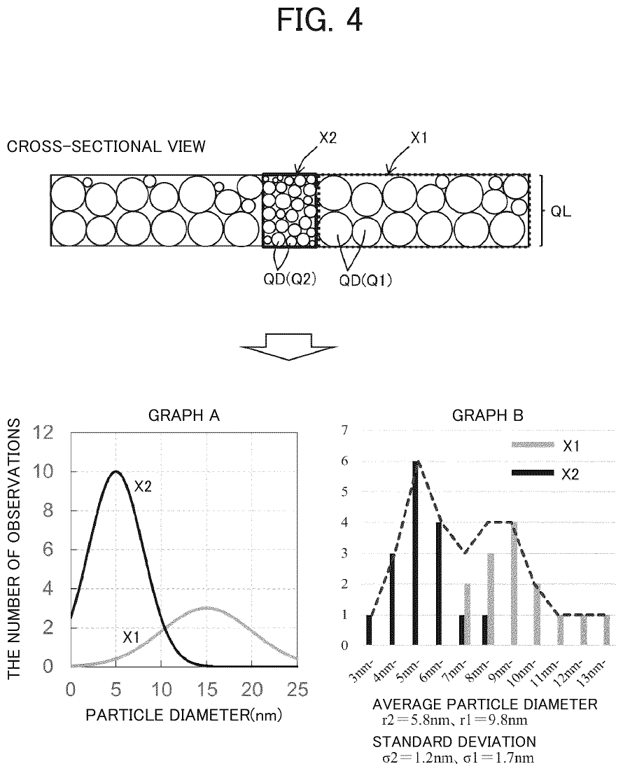

The space SP, and the first and second quantum dots Q1 and Q2 may be specified as below. FIG. 4 illustrates the particle diameter distribution of the quantum dot layer. The cross-sectional view in FIG. 4 is an example of the quantum dot layer QL in cross-sectional view, and the graphs A and B in FIG. 4 each show the relationship between the particle diameter and the number of observations. First, in the cross section of the quantum dot layer QL taken along a plane parallel to its thickness direction, measurements are performed on the particle diameters (the diameters of circles having the same area shall be defined as particle diameters) of the quantum dots QD (e.g., 10 to 100 quantum dots) observed in any two regions (the region X1 and the region X2) including the entire quantum dot layer QL in the thickness direction. Next, calculations are performed on the average particle diameter, r1, and standard deviation σ1 in the region X1, and the average particle diameter, r2, and standard deviation σ2 in the region X2. Here, where (r1−r2)≥1.0×(σ1+σ2) is satisfied, it may be determined that the particle diameter distribution of the quantum dots QD contained in the region X1 is different from the particle diameter distribution of the quantum dots QD contained in the region X2, that is, it may be determined that there is a region X2 (the cross-sectional region of the space SP) absent from the first quantum dots Q1 penetrating the quantum dot layer QL. In the graphs A and B in FIG. 4, r1 measures 9.8 nm, r2 measures 5.8 nm, σ1 measures 1.7 nm, and σ2 measures 1.2 nm, thus, (r1−r2)≥1.0×(σ1+σ2) is satisfied. As such, where such X1 and X2 are selected, it may be determined that “the particle diameter distribution of the quantum dots QD contained in the region X1 is different from the particle diameter distribution of the quantum dots QD contained in the region X2”, and that “there is a space (region X2) absent from the first quantum dots Q1 penetrating the quantum dot layer QL, and the second quantum dots Q2 having a smaller particle diameter than the first quantum dots Q1 are disposed within this space (region X2)”.

The first and second quantum dots Q1 and Q2 may be specified in accordance with composition. For instance, where two kinds of quantum dots QD whose compositions are different can be detected through element analysis, the two particle diameter distributions D1 (the average particle diameter r1, the standard deviation σ1) and D2 (the average particle diameter r2, the standard deviation σ2) can be obtained on the basis of these compositions as a dividing condition. In response to the fact that the particle diameter distributions D1 and D2 satisfy (r1−r2)≥1.0×(σ1 +σ2), and in response to an observation that a region containing only quantum dots (quantum dots of the same composition) belonging to the particle diameter distribution D2 penetrates the quantum dot layer QL, it may be determined that “there is a space (SP) absent from the first quantum dots Q1 penetrating the quantum dot layer QL”.

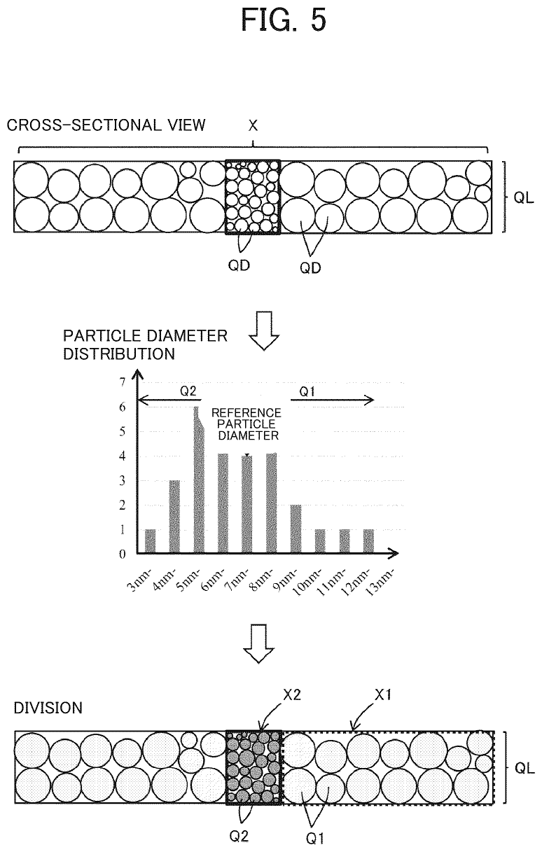

The space SP, and the first and second quantum dots Q1 and Q2 may be specified as below. FIG. 5 illustrates the particle diameter distribution of the quantum dot layer. First, in the cross section of the quantum dot layer QL taken along a plane parallel to its thickness direction, measurements are performed on the particle diameters (the diameters of circles having the same area shall be defined as particle diameters) of the quantum dots QD (e.g., 10 to 100 quantum dots) observed in any region X including the entire quantum dot layer Q1 in the thickness direction. There are two particle diameter peaks, and between them is a reference particle diameter at which the number of observations is a minimum value; here, the quantum dot QD having a particle diameter equal to or smaller than the reference particle diameter is defined as the second quantum dot Q2, and the quantum dot QD having a particle diameter larger than the reference particle diameter is defined as the first quantum dot Q1. Next, based on this condition using the reference particle diameter, the quantum dots QD observed in the region X are divided into the first quantum dot Q1 or the second quantum dot Q2, and when there is a region with only the second quantum dots Q2, penetrating the quantum dot layer QL, it may be determined that “there is a region absent from the first quantum dots Q1 penetrating the quantum dot layer QL”. In the region X illustrated in FIG. 5, a first peak=5.5 nm, a second peak=8.0 nm, and a reference particle diameter (minimum value)=7.0 nm can be set; in accordance with a criterion in which those having a particle diameter greater than 7.0 nm are specified as the first quantum dots Q1, and those having a particle diameter equal to or less than 7.0 nm are specified as the second quantum dots Q2, the quantum dots undergo tone-division for each particle diameter on a cross-sectional photograph, and where a region containing only the second quantum dots Q2 penetrates the quantum dot layer QL, it may be determined that “there is a region (a region with only Q2) absent from Q1 penetrating the quantum dot layer QL”.

The space SP, and the first and second quantum dots Q1 and Q2 may be specified as below.

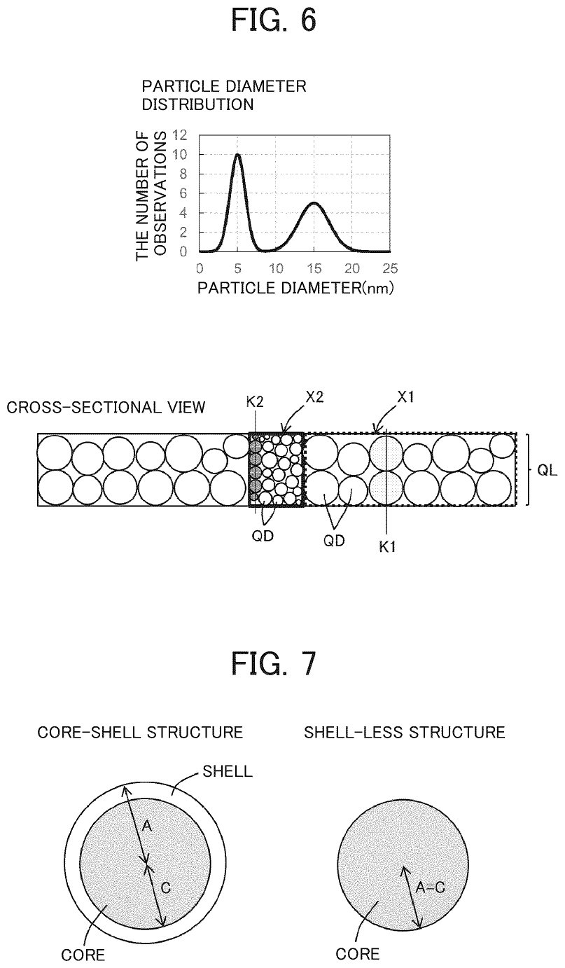

FIG. 6 is a cross-sectional view of the configuration of the quantum dot layer. First, as illustrated in FIG. 6, any two straight lines (a straight line K1 and a straight line K2) are drawn on the cross section of the quantum dot layer QL taken along a plane parallel to its thickness direction, so as to penetrate the quantum dot layer QL in the thickness direction. Where the particle diameters (the diameters of circles having equal areas shall be defined as particle diameters) of all the penetrating quantum dots QD on the straight line K2 are smaller than the particle diameters of all the penetrating quantum dots QD on the straight line K1, the straight line K2 can be regarded as a straight line longitudinally traversing a region containing only the second quantum dots Q2; hence, it may be determined that there is a region absent from the first quantum dots Q1 penetrating the quantum dot layer QL (a region containing only the second quantum dots Q2). With regard to the straight lines K1 and K2 in FIG. 6, the penetrating quantum dots QD on the straight line K1 are composed of one 12-nm-particle-sized quantum dot and one 14-nm-particle-sized quantum dot, and the penetrating quantum dots QD on the straight line K2 are composed of two 4-nm-particle-sized quantum dots and four 5-nm-particle-sized quantum dots. This fact falls under the foregoing “the particle diameters of all the penetrating quantum dots QD on the straight line K2 are smaller than the particle diameters of all the penetrating quantum dots QD on the straight line K1”; hence, it may be determined that “the straight line K2 is a straight line longitudinally traversing a region containing only Q2”, and that “there is a region absent from Q1 penetrating the quantum dot layer QL (a region containing only Q2)”.

As described, any one of the methods illustrated in FIG. 2 to FIG. 6 for instance can specify the space SP absent from the first quantum dots Q1 penetrating the quantum dot layer QL. However, how to specify the space SP, the first quantum dots Q1, and other things is not limited to these methods. Other methods may be used for the specification. Further, although the region X1 in FIG. 2 to FIG. 6 is any cross-sectional region including the entire quantum dot layer QL in the thickness direction, the region X1, which in some cases contains the third quantum dots Q3 at either end or both ends in the thickness direction (i.e., the upper end and the lower end), does not necessarily have to be “any cross-sectional region including the entire quantum dot layer QL in the thickness direction”. The region X1 may be “a region excluding at least one of the upper and lower ends of any cross-sectional region including the entire quantum dot layer QL in the thickness direction”.

In this embodiment, the second-quantum-dot assembly ZS is disposed in the space SP (through space), thereby enabling reduction of the leakage current between the first carrier transport layer T1 and the second carrier transport layer T2, thus improving light emission efficiency (EQE).

Where the band gap of the second quantum dots Q2 is larger than the band gap of the first quantum dots Q1, excitons entered the second quantum dots Q2 move away to the first quantum dots Q1 immediately, and recombination for light emission is hence less likely to occur in the second quantum dots Q2. This considerably prevents the second quantum dots Q2 from light emission, thus enhancing the efficiency of light emission in the first quantum dots Q1. Furthermore, the color purity of light emitted from the quantum dot layer QL is also enhanced.

The cores of the second quantum dots Q2 have a band gap of 5.8 eV or less, 4.0 eV or less, or 3.5 eV or less. This can avoid visible-light emission in the second quantum dots Q2 while preventing the hole blocking function of the second quantum dots Q2, and this can prevent rise in applied voltage, thereby reducing consumed electric power.

The second quantum dots Q2 may be configured not to emit light at a wavelength of 400 nm or greater. Accordingly, even if the second quantum dots Q2 emits (electroluminescent) light, this light can be visually recognized little, thus enabling color purity enhancement. The second quantum dots Q2 may be configured not to emit light in a visible-light range (370 nm or greater).

The third-quantum-dot assembly ZT with a small average particle diameter is disposed on the upper and lower sides of the first-quantum-dot assembly ZF, thus enabling improvement in the roughness (reduction in the surface roughness) of the quantum dot layer QL. This improvement of the roughness of the quantum dot layer QL prevents current concentration at a particular site, thus improving light emission efficiency and reliability.

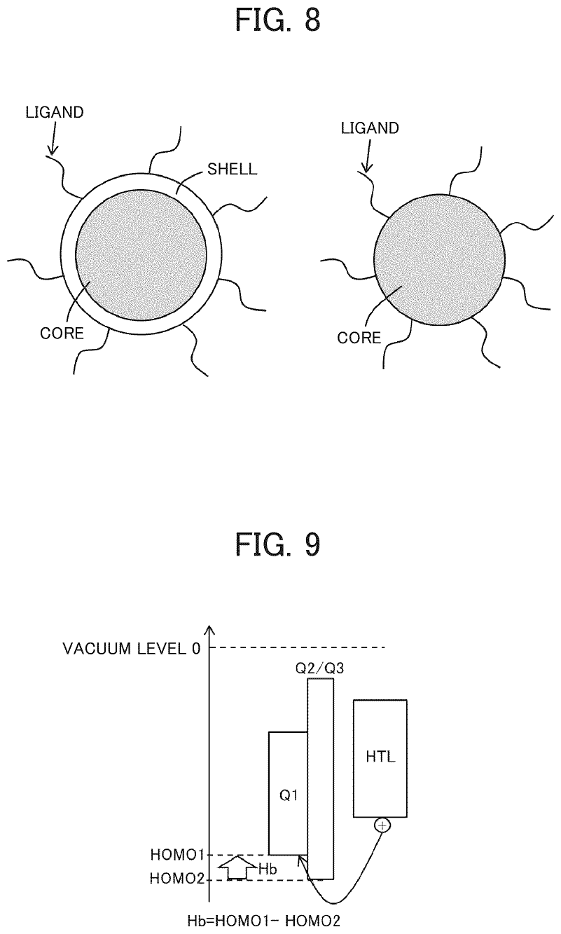

FIG. 7 and FIG. 8 are schematic diagrams each illustrating an example of the configuration of the first quantum dot, and an example of the configuration of the second quantum dot. Each first quantum dot Q1 may have a core-shell structure (a particle diameter A>a core diameter C) or a shell-less (an exposed core without a shell) structure (the particle diameter A=the core diameter C). Each second quantum dots Q2 may also have a core-shell structure or a shell-less structure.

The second quantum dot Q2 that has a core-shell structure has fewer surface defects and is thus less likely to exhibit non-light-emission recombination at a defect level. This improves light emission efficiency.

The core diameter C of each second quantum dot Q2 may be smaller than the core diameter C of each first quantum dot Q1. This enables the band gap of the second quantum dot Q2 to be larger than the band gap of the first quantum dot Q1 (for instance, this enables LUMO2 to be shallower than LUMO1, that is, enables LUMO2 to be close to a vacuum level), while using the same semiconductor material for the cores of the first quantum dot Q1 and second quantum dot Q2. The same material may be used for the shells of the first quantum dot Q1 and second quantum dot Q2. This enables the first quantum dot Q1 and the second quantum dot Q2 to be produced using the same manufacturing apparatus through almost the same process, thereby enabling manufacturing-cost saving.

For the cores of the first quantum dots Q1 and second quantum dots Q2, a semiconductor material may be used that exhibits a smaller change in HOMO than a change in LUMO when its particle diameter is reduced (for example, LUMO becomes shallower as the core diameter decreases, but HOMO does not substantially change). A light-emitting element including quantum dots, which is commonly electron-rich, improves carrier balance and reduces consumed electric power.

As illustrated in FIG. 8, ligands may be disposed on the surface of at least one of the first quantum dot Q1 and second quantum dot Q2. Proving ligands (preferably, ligands of the same configuration) on the first quantum dot Q1 and second quantum dot Q2 can prevent the second quantum dot Q2 from adversely affecting the properties of the first quantum dot Q1.

In the light-emitting element 10, the thickness of the quantum dot layer QL may be four times or less of the particle diameter of the first quantum dots Q1, three times or less of the same, or two times or less of the same. Where the first-quantum-dot assembly ZF has a single-layer structure of the first quantum dots Q1 (see FIG. 1) or a multilayer structure of several layers, the space SP (through space) is easily formed in the quantum dot layer QL, thus increasing the benefit of providing the second-quantum-dot assembly ZS.

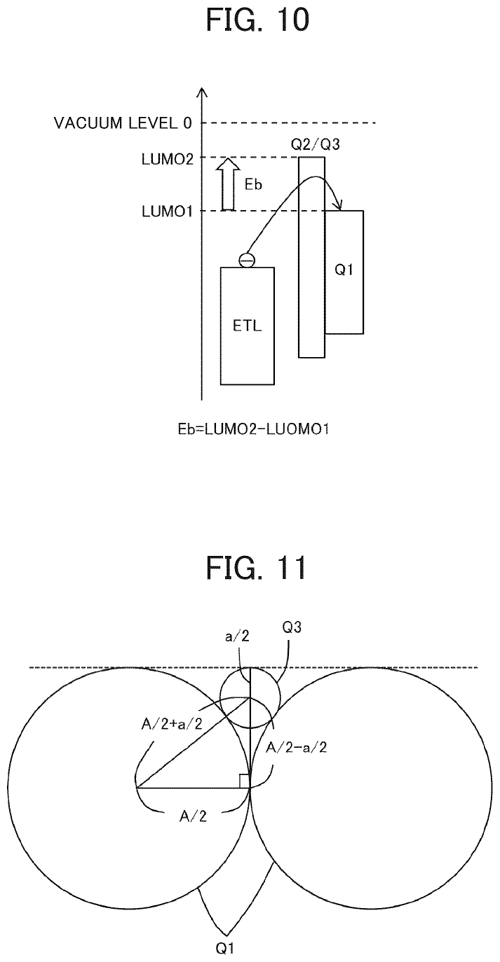

FIG. 9 and FIG. 10 are schematic diagrams illustrating the energy level of each quantum dot. In the light-emitting element 10, a level difference Hb between the energy level, HOMO1, of the highest occupied molecular orbital of the core of each first quantum dot Q1 and the energy level, HOMO2, of the highest occupied molecular orbital of the core of each second quantum dots Q2 (Hb=HOMO1−HOMO2) may be set smaller than a level difference Eb between the energy level, LUMO1, of the lowest unoccupied molecular orbital of the cores of the first quantum dots Q1 and the energy level, LUMO2, of the lowest unoccupied molecular orbital of the cores of the second quantum dots Q2 (Eb=LUMO2−LUMO1).

Satisfying this condition (Hb<Eb) can weaken the inhibition of hole transfer (when compared to the inhibition of electron transfer) with regard to the inhibition of carrier transfer caused by the second quantum dots Q2 and can thus improve carrier balance in a quantum-dot light-emitting element, which is commonly electron-rich.

The light-emitting element 10 may be configured such that the level difference Hb is below 1.0 [eV], where [eV] is the unit of the energy levels of the highest occupied molecular orbital and lowest unoccupied molecular orbital. Setting the level difference Hb, which is an energy barrier for holes, at below 1.0 eV as described can prevent the second quantum dots Q2 from the function of inhibiting hole transfer to the first quantum dots Q1 (hole blocking function), thereby enabling carrier balance enhancement. In addition, this setting can reduce the applied voltage (a voltage necessary to cause the element to emit light at a predetermined luminance level) between the first electrode E1 and the second electrode E2, thereby enabling reduction in consumed electric power. The level difference Hb may be below 0.5 [eV] or below 0.2 [eV].

FIG. 9 shows HOMO2<HOMO1 (HOMO1 is closer to the vacuum level than HOMO2) by way of example. HOMO2≥HOMO1 may be satisfied (HOMO2 may be at the same level as HOMO1 or may be closer to the vacuum level than HOMO1). In this case, the level difference Hb stands at zero or a negative value, thereby improving carrier balance and reducing applied voltage. HOMO of the cores of the second quantum dots Q2 or HOMO of the shells of the second quantum dots Q2 may be HOMO2.

In FIG. 10, setting LUMO2>LUMO1 (LUMO2 is closer to the vacuum level than LUMO1), and setting the level difference Eb (=LUMO2−LUMO1) at 0 or greater, or greater than 0.2 eV causes the second quantum dots Q2 to inhibit electron transfer to the first quantum dots Q1 (electron blocking function), thereby enabling carrier balance enhancement. LUMO of the cores of the second quantum dots Q2 or LUMO of the shells of the second quantum dots Q2 may be LUMO2.

In FIG. 1, the third quantum dots Q3 and the second quantum dots Q2 have the same configuration (the same level structure), and the third quantum dots Q3 located around the first-quantum-dot assembly ZF can hence improve carrier balance.

The second quantum dots Q2 may contain at least one of a Group IV single element that is not carbon, a Group IV compound, a Group III-V compound that is not a nitride, a Group II-VI compound, a Group II-IV-V chalcopyrite compound, and a Group I-III-VI chalcopyrite compound.

The Group IV single element may be Si or Ge. The Group IV compound may be SiGe. The Group III-V compound may be AlP, AlAs, AlSb, GaP, GaAs, GaSb, InP, InAs, InSb, AlPAs, AlPSb, AlAsSb, GaPAs, GaPSb, GaAsSb, InPAs, InPSb, InAsSb, AlGaPAs, AlGaPSb, AlGaAsSb, AlInPAs, AlInPSb, AlInAsSb, GaInPAs, GaInPSb, or GaInAsSb. The Group II-VI compound may be ZnSe, ZnTe, CdO, CdS, CdSe, CdTe, HgS, HgSe, HgTe, ZnSeTe, CdSSe, CdSTe, CdSeTe, HgSSe, HgSTe, HgSeTe, ZnCdSSe, ZnCdSTe, ZnCdSeTe, ZnHgSSe, ZnHgSTe, ZnHgSeTe, CdHgSSe, CdHgSTe, or CdHgSeTe. The Group II-IV-V chalcopyrite compound may be ZnSiP₂, ZnSiAs₂, ZnSiSb₂, ZnGeP₂, ZnGeAs₂, ZnGeSb₂, ZnSnP₂, ZnSnAs₂, ZnSnSb₂, CdSiP₂, CdSiAS₂, CdSiSb₂, CdGeP₂, CdGeAs₂, CdGeSb₂, CdSnP₂, CdSnAs₂, or CdSnSb₂. The Group I-III-VI chalcopyrite compound may be CuAlSe₂, CuAlTe₂, CuGaS₂, CuGaSe₂, CuGaTe₂, CuInS₂, CuInSe₂, CuInTe₂, AgAlSe₂, AgAlTe₂, AgGaS₂, AgGaSe₂, AgGaTe₂, AgInS₂, AgInSe₂, or AgInTe₂. However, the single element and compounds are not limited to the foregoing.

Further, the Group IV single element may be C, the Group IV compound may be SiC, the Group II-VI compound may be ZnO or ZnS, and the Group I-III-VI chalcopyrite compound may be CuAlS₂ or AgAlS₂. However, the single element and compounds are not limited to the foregoing.

FIG. 11 is a schematic diagram illustrating an example of the configuration of the third quantum dot. Let the particle diameter of the first quantum dots Q1 be defined as A, and let the particle diameter of the third quantum dots Q3 be defined as a. Accordingly, as illustrated in FIG. 11, the expression (A/2)²+(A/2−a/2)²=(A/2+a/2)² is satisfied in a=A/4; thus, setting the particle diameter a of the third quantum dots Q3 to be one-fourth or less of the particle diameter A of the first quantum dots Q1 can enhance roughness improvement. In the light-emitting element 10, the third quantum dots Q3 and the second quantum dots Q2 have the same configuration, thus enabling the particle diameter of the second quantum dots Q2 to be one-fourth or less of the particle diameter of the first quantum dots Q1.

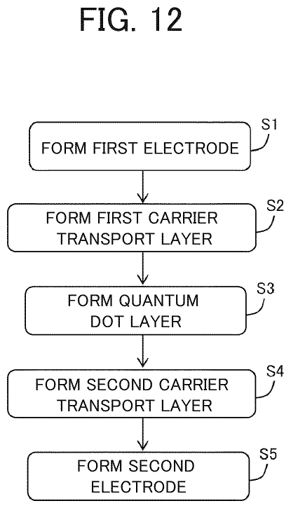

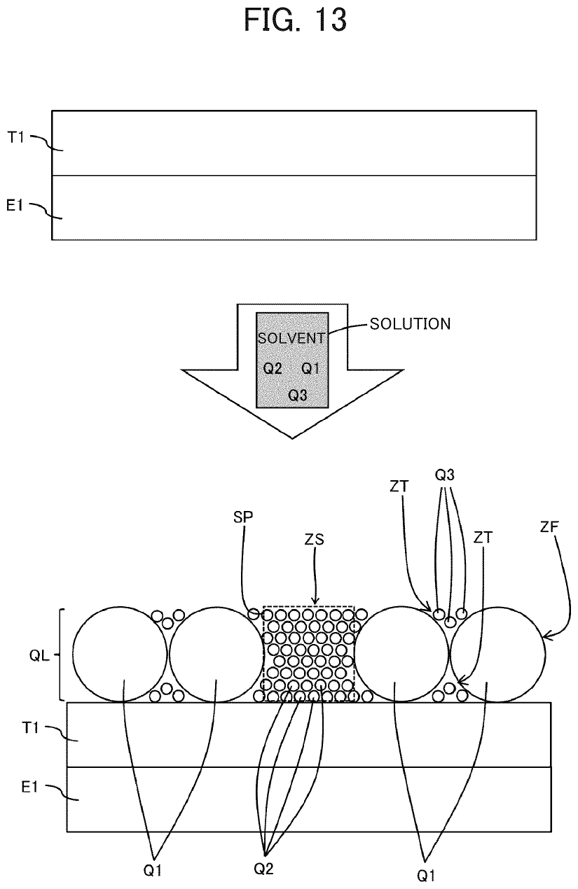

FIG. 12 is a flowchart showing a method for manufacturing the light-emitting element according to the first embodiment. FIG. 13 is a cross-sectional view of the light-emitting element according to the first embodiment in the process of being manufactured. In FIG. 12, Step S1 (first step) is forming the first electrode E1, Step S2 is forming the first carrier transport layer T1, Step S3 (second step) is forming the quantum dot layer QL, Step S4 is forming the second carrier transport layer T2, and Step S5 (third step) is forming the second electrode E2. Step S2 may include forming a hole transport layer (HTL), and Step S4 may include forming an electron transport layer (ETL) (in the case of a conventional structure). Step S2 may include forming an ETL, and Step S4 may include forming an HTL (in the case of an inverted structure).

For a conventional structure, Step S2 is applying a solution containing an HTL material dispersed in, for instance, a chlorobenzene solvent, and removing the solvent. Usable examples of the HTL material include Poly-4-butyl-N,N-diphenylaniline (Poly-TPD), Poly[(9,9-dioctylfluorenyl-2,7-diyl)-co-(4,4′-(N-(4-sec-butylphenyl))diphenylamine)] (TFB), and Poly(9-vinylcarbazole) (PVK).

A hole injection layer (HIL, containing, for instance, NiO, PEDOT:PSS, or MoO₃) may be formed between Step S1 and Step S2. Step S4 is applying a solution containing an ETL material, which is herein nanoparticles (e.g., ZnO nanoparticles), dispersed in a solvent (e.g., methanol, ethanol, propanol, butanol, or a mixed solvent of these materials), and removing the solvent.

Step S3 is, as shown in FIG. 12, applying a solution containing the first quantum dots Q1, the second quantum dots Q2, and the third quantum dots Q3 having the same configuration as the second quantum dots Q2, as well as a solvent (e.g., octane) for dispersing these quantum dots onto the first carrier transport layer T1 (for a conventional structure, an HTL; for an inverted structure, an ETL), and removing the solvent. At this time, as illustrated in FIG. 13, the second quantum dots Q2, having a smaller particle diameter than the first quantum dots Q1, are disposed in the space SP, which is absent from the first quantum dots Q1 penetrating the quantum dot layer QL in its thickness direction. In addition, the third quantum dots Q3, having a smaller particle diameter than the first quantum dots Q1, are disposed on the upper and lower sides of the first quantum dots Q1. The third quantum dots Q3 have the same configuration as the second quantum dots Q2.

As described above, applying a solution containing a mixture of the first quantum dots Q1 and second quantum dots Q2 can form the quantum dot layer in a single process step. In this case, using the same ligand (see FIG. 8) for the first quantum dots Q1 and second quantum dots Q2 reduces the possibility that the second quantum dots Q2 can adversely affect the properties of the first quantum dots Q1. Using the same ligand can also form the quantum dot layer QL in a single process step, which is preferable in view of manufacturing cost.

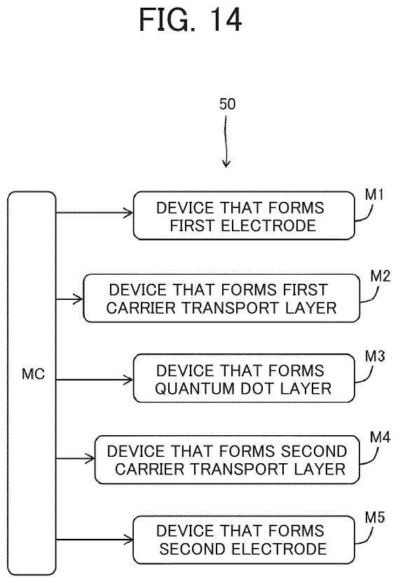

FIG. 14 is a block diagram illustrating an apparatus that manufactures the light-emitting element according to the first embodiment. The apparatus, 50, that manufactures the light-emitting element is provided with the following: a device M1 that forms the first electrode E1; a device 2 that forms the first carrier transport layer T1; a device M3 that forms the quantum dot layer QL; a device M4 that forms the second carrier transport layer T2; a device M5 that forms the second electrode E2; and a control device MC having a processor and a memory for controlling the devices M1 to M5.

### Second Embodiment

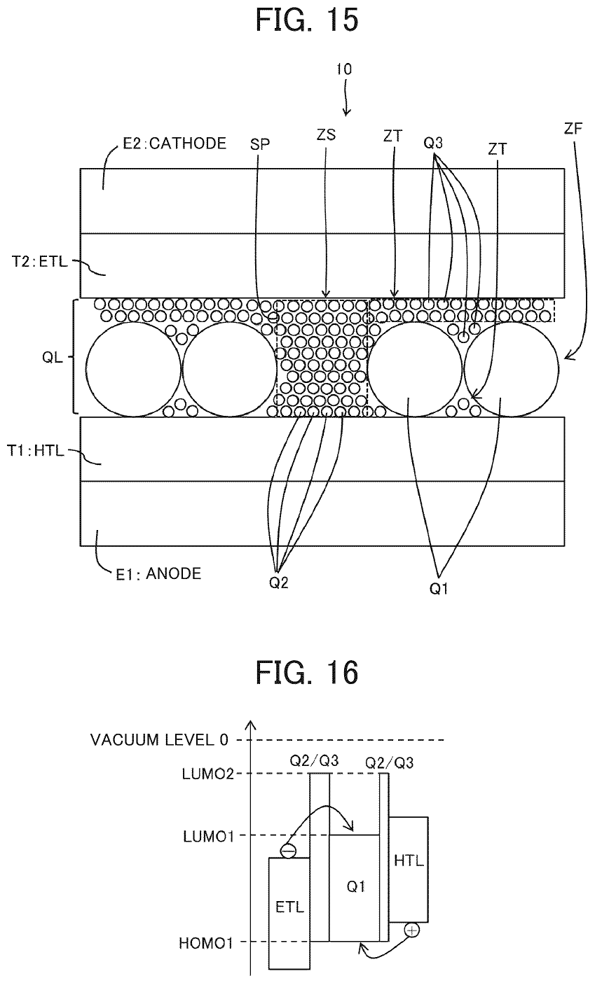

FIG. 15 is a cross-sectional view of an example of the configuration of a light-emitting element according to a second embodiment. FIG. 16 is a schematic diagram illustrating energy levels in the configuration in FIG. 15. The light-emitting element 10 according to the second embodiment is provided with the following: the first electrode E1 and the second electrode E2; and the quantum dot layer QL disposed between the first electrode E1 and the second electrode E2, and including the first quantum dots Q1. In FIG. 15, the light-emitting element 10 has a conventional structure with an anode being on the lower side; further, the first electrode E1 is an anode, and the second electrode E2 is a cathode. The first carrier transport layer is an HTL, and the second carrier transport layer is an ETL.

The quantum dot layer QL includes the space SP absent from the first quantum dots Q1 penetrating the quantum dot layer QL in the thickness direction TD. The space SP contains the second quantum dots Q2 having a smaller particle diameter than the first quantum dots Q1. The band gap of the second quantum dots Q2 may be larger than the band gap of the first quantum dots Q1. The cores of the second quantum dots Q2 have a band gap of 5.8 eV or less, 4.0 eV or less, or 3.5 eV or less for instance.

The space SP contains the second-quantum-dot assembly ZS including the second quantum dots Q2. The second-quantum-dot assembly ZS has a multilayer structure in which the second quantum dots Q2 are included in the individual layers and is filled in the space SP. The volume of the space SP may be larger than the volume of the first quantum dots Q1.

The quantum dot layer QL includes the first-quantum-dot assembly ZF including the first quantum dots Q1, and the third-quantum-dot assembly ZT including the third quantum dots Q3 having a smaller particle diameter than the first quantum dots Q1. The third quantum dots Q3 have the same configuration as the second quantum dots Q2 (the same material, the same size, the same structure, and the same band gap) and have a larger band gap than the first quantum dots Q1.

In the second embodiment, the first-quantum-dot assembly ZF is in contact with the HTL (first carrier transport layer), and the third-quantum-dot assembly ZT is disposed higher than the top of the first-quantum-dot assembly ZF and is in contact with the ETL (second carrier transport layer). The third-quantum-dot assembly ZT has a multilayer structure in which the third quantum dots Q3 are included in the individual layers. It is noted that the third-quantum-dot assembly ZT is also disposed between the HTL (first carrier transport layer) and the first-quantum-dot assembly ZF.

The first-quantum-dot assembly ZF in the second embodiment may be covered with the second-quantum-dot assembly ZS and the third-quantum-dot assembly ZT. The thickness (maximum thickness) of the third-quantum-dot assembly ZT is smaller than the thickness (maximum thickness) of the first-quantum-dot assembly ZF. This can prevent a large rise in voltage applied between the first electrode E1 and the second electrode E2.

In the first-quantum-dot assembly ZF, the ratio of the first quantum dots being in contact with the ETL (second carrier transport layer) may be smaller than the ratio of the first quantum dots being in contact with the third-quantum-dot assembly ZT. To be specific, the ratio of the first quantum dots Q1 being in contact with the ETL (second carrier transport layer) may be 10% or less in the first-quantum-dot assembly ZF. Further, the ratio of the first quantum dots being in contact with the third-quantum-dot assembly ZT may be 75% or greater in the first-quantum-dot assembly ZF.

The quantum dot layer QL includes the second-quantum-dot assembly ZS disposed in the space SP (through space), which is absent from the first quantum dots Q1, thereby enabling reduction of the leakage current between the first carrier transport layer T1 and the second carrier transport layer T2, thus improving light emission efficiency (EQE). The space SP is entirely filled with the second quantum dots Q2, thus highly preventing the leakage current. The light-emitting element 10 in FIG. 15 has the function that the third-quantum-dot assembly ZT over the first-quantum-dot assembly ZF inhibits electron transfer to the first quantum dots Q1 (electron blocking function), as illustrated in FIG. 16, thereby enabling carrier balance enhancement.

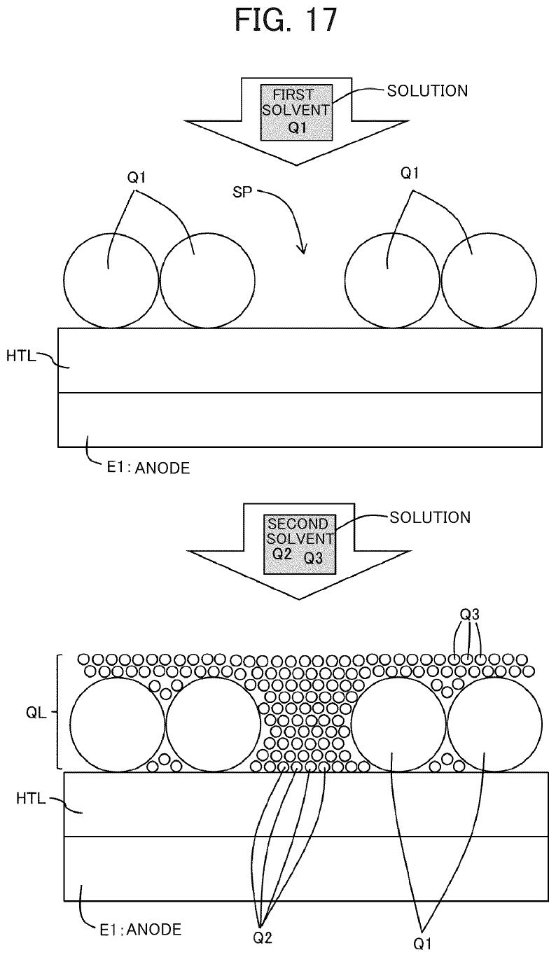

FIG. 17 is a cross-sectional view of the light-emitting element according to the second embodiment in the process of being manufactured. The method in the second embodiment includes applying a solution containing the first quantum dots Q1 and a first solvent onto the HTL, followed by removing the first solvent, followed by applying a solution containing the second quantum dots Q2, the third quantum dots Q3, and a second solvent, followed by removing this solvent. One of the first and second solvents may be a non-polar solvent, and the other may be a polar solvent. This can prevent bulk reduction (elution) of the first-quantum-dot assembly ZF when the solution containing the second quantum dots Q2 are applied.

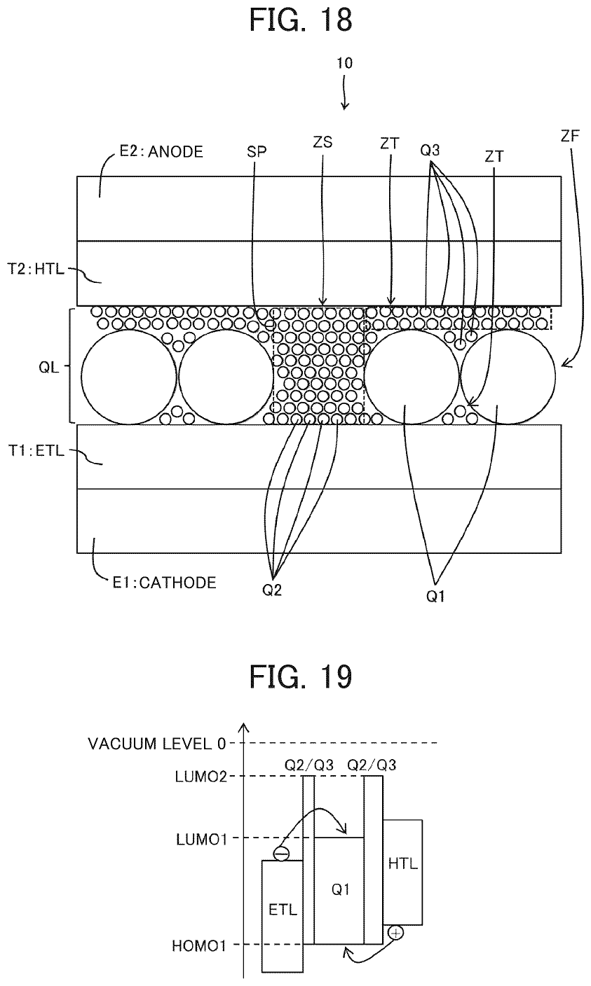

FIG. 18 is a cross-sectional view of another example of the configuration of the light-emitting element according to the second embodiment. FIG. 19 is a schematic diagram illustrating energy levels in the configuration in FIG. 18. The first electrode E1 is a cathode, and the second electrode E2 is an anode. The first carrier transport layer is an ETL, and the second carrier transport layer is an HTL.

In FIG. 18, the first-quantum-dot assembly ZF is in contact with the ETL (first carrier transport layer), and the third-quantum-dot assembly ZT is disposed higher than the top of the first-quantum-dot assembly ZF and is in contact with the HTL (second carrier transport layer). The third-quantum-dot assembly ZT has a multilayer structure in which the third quantum dots Q3 are included in the individual layers.

The light-emitting element 10 in FIG. 18 (having an inverted structure in which the cathode is on the lower side) has almost no function (hole blocking function) that the third-quantum-dot assembly ZT over the first-quantum-dot assembly ZF hinders hole transfer to the first quantum dots Q1 (because HOMO changes little even if the particle diameter is reduced), thereby enabling carrier balance retention (see FIG. 19). In addition, the third quantum dots Q3, which have almost no hole blocking function, changes the properties little even if the thickness of the third-quantum-dot assembly ZT varies more or less depending on production process, and thus, the third quantum dots Q3 are preferable for mass production.

### Third Embodiment

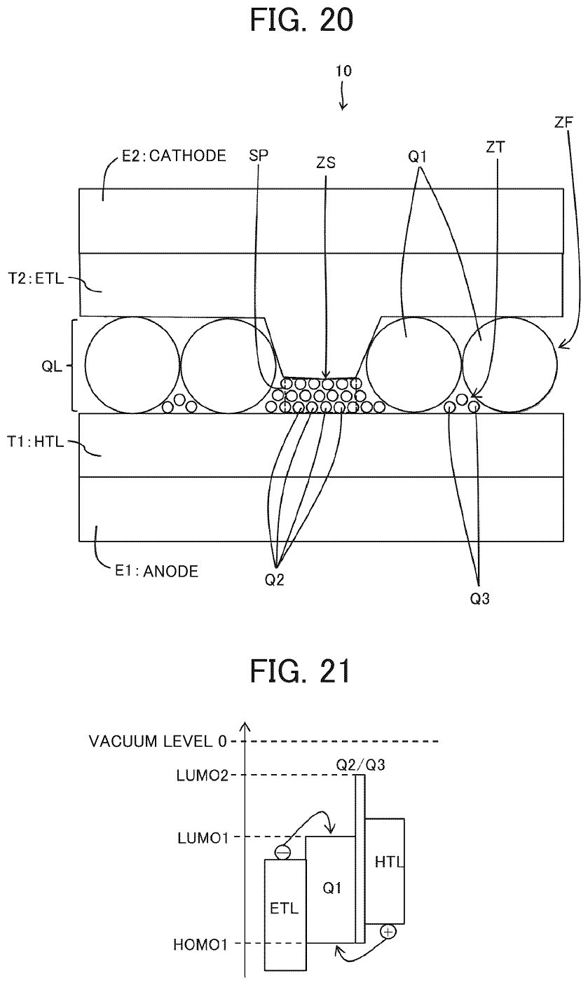

FIG. 20 is a cross-sectional view of an example of the configuration of a light-emitting element according to a third embodiment. FIG. 21 is a schematic diagram illustrating energy levels in the configuration in FIG. 20. The light-emitting element 10 according to the third embodiment is provided with the following: the first electrode E1 and the second electrode E2; and the quantum dot layer QL disposed between the first electrode E1 and the second electrode E2, and including the first quantum dots Q1. In FIG. 20, the light-emitting element 10 has a conventional structure; further, the first electrode E1 is an anode, and the second electrode E2 is a cathode. The first carrier transport layer T1 is an HTL, and the second carrier transport layer T2 is an ETL.

The quantum dot layer QL includes the space SP absent from the first quantum dots Q1 penetrating the quantum dot layer QL in the thickness direction TD. The space SP contains the second quantum dots Q2 having a smaller particle diameter than the first quantum dots Q1. The band gap of the second quantum dots Q2 is larger than the band gap of the first quantum dots Q1. The cores of the second quantum dots Q2 have a band gap of 5.8 eV or less, 4.0 eV or less, or 3.5 eV or less for instance.

The space SP contains the second-quantum-dot assembly ZS including the second quantum dots Q2. The second-quantum-dot assembly ZS is disposed on the lower side (HTL side) in the space SP and is in contact with the HTL.

The quantum dot layer QL includes the second-quantum-dot assembly ZS disposed in the space SP (through space), which is absent from the first quantum dots Q1, thereby enabling reduction of the leakage current between the first carrier transport layer T1 and the second carrier transport layer T2, thus improving light emission efficiency (EQE).

FIG. 20 illustrates a configuration in which the second-quantum-dot assembly ZS and the third-quantum-dot assembly ZT are in contact with the HTL; this configuration has almost no function (hole blocking function) that the second-quantum-dot assembly ZS and the third-quantum-dot assembly ZT hinder hole transfer to the first quantum dots Q1 (because HOMO changes little even if the particle diameter is reduced), thereby enabling carrier balance retention (see FIG. 21).

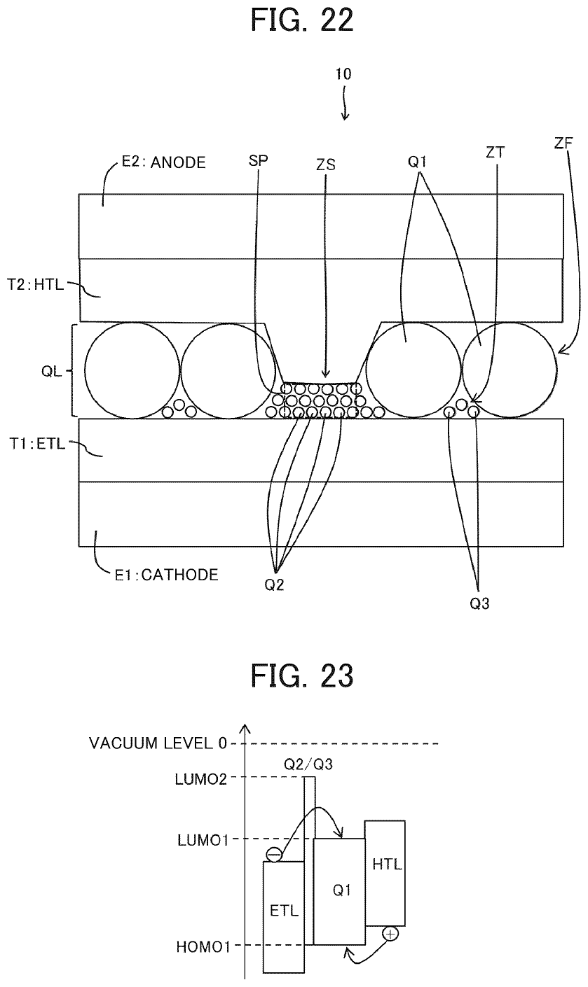

FIG. 22 is a cross-sectional view of another example of the configuration of the light-emitting element according to the third embodiment. FIG. 23 is a schematic diagram illustrating energy levels in the configuration in FIG. 22. The first electrode E1 is a cathode, and the second electrode E2 is an anode. The first carrier transport layer T1 is an ETL, and the second carrier transport layer T2 is an HTL.

The second-quantum-dot assembly ZS in FIG. 22 is disposed on the lower side (ETL side) in the space SP and is in contact with the ETL. This produces the function that the second-quantum-dot assembly ZS and the third-quantum-dot assembly ZT inhibit electron transfer to the first quantum dots Q1 (electron blocking function), thereby enabling carrier balance enhancement (see FIG. 23).

### Fourth Embodiment

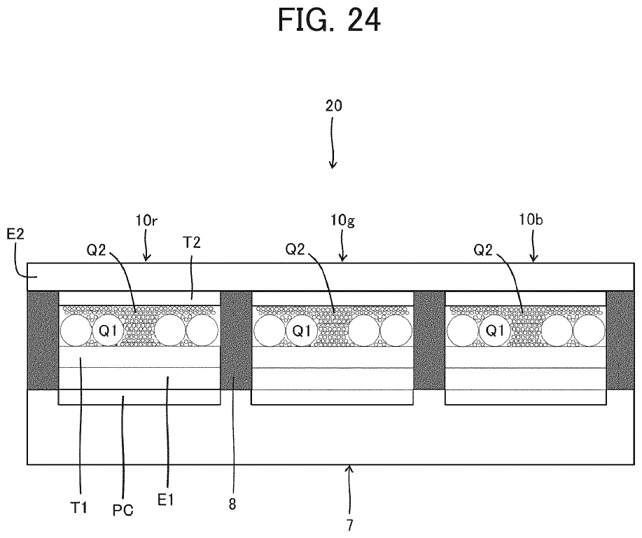

FIG. 24 is a cross-sectional view of an example of the configuration of a display device according to a fourth embodiment. As illustrated in FIG. 24, the display device, 20, has a light-emitting element 10r that emits red light, a light-emitting element 10g that emits green light, and a light-emitting element 10b that emits blue light. The light-emitting elements 10r, 10g, and 10b are formed on a driving substrate 7 (e.g., a pixel circuit substrate including TFTs) and are partitioned by an insulating partition wall 8. The diving substrate 7 is provided with pixel circuits PC corresponding to the respective light-emitting elements 10r, 10g, and 10b.

The core particle diameter or core material of the first quantum dots Q1 may be different between the light-emitting elements 10r, 10g, and 10b. The following relationship may be established: the band gap of the first quantum dots Q1 of the light-emitting element 10r<the band gap of the first quantum dots Q1 of the light-emitting element 10g<the first quantum dots Q1 of the light-emitting element 10b. The second quantum dots Q2 of the light-emitting elements 10r, 10g, and 10b may be quantum dots having a common configuration, or quantum dots having different configurations. FIG. 24 illustrates, by way of example, the light-emitting elements 10r, 10g, and 10b each of which is the light-emitting element 10 according to the second embodiment. The light-emitting element 10 according to any one of the first to fourth embodiments may be used.

### Supplemental 1

### First Aspect

A light-emitting element in the present disclosure is provided with the following:

a first electrode and a second electrode; and a quantum dot layer disposed between the first electrode and the second electrode, and including first quantum dots.

The quantum dot layer may include a space absent from the first quantum dots penetrating the quantum dot layer in the thickness direction of the quantum dot layer.

The space may contain second quantum dots having a smaller particle diameter than the first quantum dots.

### Second Aspect

The light-emitting element in the present disclosure may be configured such that the band gap of the second quantum dots is larger than the band gap of the first quantum dots.

### Third Aspect

The light-emitting element in the present disclosure may be configured such that the space contains a second-quantum-dot assembly including the second quantum dots.

### Fourth Aspect

The light-emitting element in the present disclosure may be configured such that the second-quantum-dot assembly has a multilayer structure in which the second quantum dots are included in individual layers.

### Fifth Aspect

The light-emitting element in the present disclosure may be configured such that the second-quantum-dot assembly is disposed on the lower side in the space.

### Sixth Aspect

The light-emitting element in the present disclosure may be configured such that the band gap of the second quantum dots is a gap between the energy level of the lowest unoccupied molecular orbital of the core of the second quantum dot and the energy level of the highest occupied molecular orbital of the core of the second quantum dot.

### Seventh Aspect

The light-emitting element in the present disclosure may be configured such that the first quantum dots and the second quantum dots contain a core substance that exhibits a smaller change in the energy level of the highest occupied molecular orbital resulting from a particle diameter reduction than a change in the energy level of the lowest unoccupied molecular orbital.

### Eighth Aspect

The light-emitting element in the present disclosure may be configured such that the second quantum dots have a band gap of 5.8 eV or less.

### Ninth Aspect

The light-emitting element in the present disclosure may be configured such that HOMO1−HOMO2<1.0 eV is satisfied, where HOMO1 is the energy level of the highest occupied molecular orbital of the first quantum dot, HOMO2 is the energy level of the highest occupied molecular orbital of the second quantum dot, and eV is the unit of the energy levels.

### Tenth Aspect

The light-emitting element in the present disclosure may be configured such that LUMO2>LUMO1 is satisfied, where LUMO1 is the energy level of the lowest unoccupied molecular orbital of the first quantum dot, and LUMO2 is the energy level of the lowest unoccupied molecular orbital of the second quantum dot.

### Eleventh Aspect

The light-emitting element in the present disclosure may be configured such that LUMO2>LUMO1+0.2 eV is satisfied, where eV is the unit of the energy levels.

### Twelfth Aspect

The light-emitting element in the present disclosure may be configured such that at least one of the first and second quantum dots has a surface provided with ligands.

### Thirteenth Aspect

The light-emitting element in the present disclosure may be configured such that the quantum dot layer has, in a cross-sectional view in the thickness direction, a first region including the entire thickness direction, and in which the entire cross-sections of one or more quantum dots are observed, and a second region including the entire thickness direction, and in which the entire cross-section of each of a plurality of quantum dots is observed.

The light-emitting element may be configured such that one or more quantum dots having a larger particle diameter than Pm are observed in the first region, such that the quantum dots observed in the first region and having a larger particle diameter than Pm are the first quantum dots, and such that the quantum dots observed in the second region are the second quantum dots, where Pm is the maximum particle diameter of all quantum dots observed in the second region.

### Supplemental 2

The foregoing embodiments are illustrative and descriptive rather than restrictive. It will be apparent for one of ordinary skilled in the art that various modifications can be made based on these examples and descriptions. The disclosure of each embodiment can be freely combined with other embodiments unless otherwise contradicted technically, and the disclosures are not limited to the respective embodiments.

1. A light-emitting element comprising:
a first electrode and a second electrode; and
a quantum dot layer disposed between the first electrode and the second electrode, and including first quantum dots,
wherein the quantum dot layer includes a space absent from the first quantum dots penetrating the quantum dot layer in a thickness direction of the quantum dot layer, and
the space contains second quantum dots having a smaller particle diameter than the first quantum dots.

2. (canceled)

3. The light-emitting element according to claim 1, wherein the space contains a second-quantum-dot assembly including the second quantum dots.

4. (canceled)

5. The light-emitting element according to claim 3, wherein
the second electrode is located higher than the first electrode,
the quantum dot layer includes a first-quantum-dot assembly including the first quantum dots, and a third-quantum-dot assembly including third quantum dots having a smaller particle diameter than the first quantum dots, and
the third-quantum-dot assembly is disposed between the first-quantum-dot assembly and the second electrode.

6. The light-emitting element according to claim 5, wherein the third quantum dots have a configuration identical to a configuration of the second quantum dots and have a larger band gap than the first quantum dots.

7. The light-emitting element according to claim 6, wherein the third-quantum-dot assembly has a multilayer structure in which the third quantum dots are included in individual layers.

8. (canceled)

9. The light-emitting element according to claim 6, wherein the first-quantum-dot assembly is covered with the second-quantum-dot assembly and the third-quantum-dot assembly.

10. The light-emitting element according to claim 6, wherein a thickness of the third-quantum-dot assembly is smaller than a thickness of the first-quantum-dot assembly.

11. (canceled)

12. The light-emitting element according to claim 1, wherein
each of the first quantum dots has a core-shell structure or a shell-less structure,
each of the second quantum dots has a core-shell structure or a shell-less structure, and
a diameter of a core of the second quantum dot is smaller than a diameter of a core of the first quantum dot, wherein
HOMO1−HOMO2<LUMO2−LUMO1 is satisfied, where HOMO1 is an energy level of a highest occupied molecular orbital of the core of the first quantum dot, HOMO2 is an energy level of a highest occupied molecular orbital of the core of the second quantum dot, LUMO1 is an energy level of a lowest unoccupied molecular orbital of the core of the first quantum dot, and LUMO2 is an energy level of a lowest unoccupied molecular orbital of the core of the second quantum dot.

13. (canceled)

14. The light-emitting element according to claim 1, wherein the second quantum dots do not emit light at a wavelength of 400 nm or greater.

15-22. (canceled)

23. The light-emitting element according to claim 1, wherein
LUMO2>LUMO1 is satisfied, where LUMO1 is an energy level of a lowest unoccupied molecular orbital of each of the first quantum dots, and LUMO2 is an energy level of a lowest unoccupied molecular orbital of each of the second quantum dots.

24. The light-emitting element according to claim 1, comprising:
a first carrier transport layer disposed between the first electrode and the quantum dot layer; and
a second carrier transport layer disposed between the quantum dot layer and the second electrode, wherein
the second electrode is located higher than the first electrode,
the first carrier transport layer is a hole transport layer, and
the second carrier transport layer is an electron transport layer, wherein
the quantum dot layer has a first-quantum-dot assembly including the first quantum dots, and a third-quantum-dot assembly including third quantum dots having a smaller particle diameter than the first quantum dots,
the third-quantum-dot assembly is disposed between the first-quantum-dot assembly and the electron transport layer, and
in the first-quantum-dot assembly, a ratio of the first quantum dots being in contact with the electron transport layer is 10% or less.

25-27. (canceled)

28. The light-emitting element according to claim 1, comprising:
a first carrier transport layer disposed between the first electrode and the quantum dot layer; and
a second carrier transport layer disposed between the quantum dot layer and the second electrode, wherein
the second electrode is located higher than the first electrode,
the first carrier transport layer is a hole transport layer, and
the second carrier transport layer is an electron transport layer, wherein
the quantum dot layer has a first-quantum-dot assembly including the first quantum dots, and a third-quantum-dot assembly including third quantum dots having a smaller particle diameter than the first quantum dots,
the third-quantum-dot assembly is disposed between the first-quantum-dot assembly and the electron transport layer, and
in the first-quantum-dot assembly, a ratio of the first quantum dots being in contact with the third-quantum-dot assembly is larger than a ratio of the first quantum dots being in contact with the electron transport layer.

29. The light-emitting element according to claim 1, wherein the first quantum dots and the second quantum dots contain an identical core substance.

30. The light-emitting element according to claim 1, wherein each of the second quantum dots has a core-shell structure, wherein
each of the first quantum dots has a core-shell structure, and
the first quantum dots and the second quantum dots contain an identical shell substance.

31. (canceled)

32. The light-emitting element according to claim 1, wherein the particle diameter of the second quantum dots is one-fourth or less of the particle diameter of the first quantum dots.

33. The light-emitting element according to claim 1, wherein each of the first and second quantum dots has a surface provided with ligands composed of an identical substance.

34. The light-emitting element according to claim 1, wherein
the quantum dot layer has, in a cross-sectional view in the thickness direction, a first region in which an entire cross-section of each of a plurality of quantum dots is observed, and a second region in which an entire cross-section of each of a plurality of quantum dots is observed, and
at least one of P1−P2≥1.0×(σ1+σ2) and r1−r2≥1.0×(σ1+σ2) holds true, where for a particle diameter distribution of the plurality of quantum dots observed in the first region, r1 is an average particle diameter, P1 is a particle diameter at which the plurality of quantum dots peak in number, and σ1 is a standard deviation, and where for a particle diameter distribution of the plurality of quantum dots observed in the second region, r2 is an average particle diameter, P2 is a particle diameter at which the plurality of quantum dots peak in number, and σ2 is a standard deviation.

35. A method for manufacturing a light-emitting element, comprising:
a first step of forming a first electrode;
a second step of forming a quantum dot layer including first quantum dots; and
a third step of forming a second electrode,
wherein the second step includes providing second quantum dots having a smaller particle diameter than the first quantum dots into a space absent from the first quantum dots penetrating the quantum dot layer in a thickness direction of the quantum dot layer,
wherein the second step includes performing a step of applying a solution containing the first quantum dots and a first solvent, followed by a step of applying a solution containing the second quantum dots and a second solvent.

36. (canceled)

37. The method for manufacturing the light-emitting element according to claim 35, wherein one of the first and second solvents is a non-polar solvent, and the other is a polar solvent.

38. (canceled)

39. (canceled)

40. A display device comprising the light-emitting element according to claim 1.
